(19) United States
(12) Patent Application Publication
(10) Pub. No.: US 2006/0270097 A1
(43) Pub. Date: Nov. 30, 2006

(54) Organic light emitting display and method of fabricating the same

(76) Inventors: Do-young Kim, Suwon-si (KR); Takashi Noguchi, Yongin-si (KR); Jang-yeon Kwon, Seongnam-si (KR); Jong-man Kim, Seongnam-si (KR); Ji-sim Jung, Incheon-si (KR)

Correspondence Address: CANTOR COLBURN, LLP, 55 GRIFFIN ROAD SOUTH, BLOOMFIELD, CT, 06002, US

(21) Appl. No.: 11/440,249

(22) Filed: May 24, 2006

(30) Foreign Application Priority Data
May 24, 2005 (KR) 10-2005-0043743

(51) Int. Cl. H01L 21/00

(52) U.S. Cl. 438/82

(57) ABSTRACT

An organic light emitting display includes: a substrate; a plurality of pixels which are arranged in a matrix on the substrate, each pixel having a switching transistor, a driving transistor, and an organic light emission diode (OLED). Silicon channels in the switching transistor have lower carrier mobility than silicon channels in the driving transistor. The low carrier mobility of amorphous silicon in the switching transistor prevents current leakage and the higher carrier mobility of polycrystalline silicon in the driving transistor provides a high driving speed and an extended lifetime.

This application claims priority to Korean Patent Application No. 10-2005-0043743, filed on May 24, 2005, and all the benefits accruing therefrom under 35 U.S.C. §119, and the contents of which in its entirety are herein incorporated by reference.

### BACKGROUND OF THE INVENTION

1. Field of the Invention

The present invention relates to an active matrix thin film transistor (“TFT”) organic light emitting display and a method of fabricating the same.

2. Description of the Related Art

In active matrix color display devices using organic light emitting diodes (“OLEDs”), each of a plurality of pixels is formed as a circuit including two transistors and one capacitor (“2t-1C”) structure. In particular, the circuit includes a switching transistor sampling an analog image signal, a memory capacitor storing the image signal, and a driving transistor controlling current supplied to the OLED according to voltages of image signals accumulated in the memory capacitor.

In general, channels in the switching transistor and in the driving transistor are formed of amorphous crystalline silicon or polycrystalline silicon. Amorphous crystalline silicon has drawbacks such as low carrier mobility, a difficulty to drive at high speed, and, in particular, short lifetime because of drastic degradation caused by a high current of the driving transistor.

In polycrystalline silicon, the carrier mobility is high and degradation due to a high current is remarkably lower than that in amorphous crystalline silicon. However, the drawback of polycrystalline silicon is the generation of a high off-current caused by current leakage through grain boundaries.

In addition, polycrystalline silicon has low uniformity such that it is difficult to make each of a plurality of pixels have a uniform operational characteristic. A voltage program (Sarnoff, refer to 1998 Society for Information Display (SID) International Symposium (SID98)) and a current program (Sony, refer to 2001 Society for Information Display (SID) International Symposium (SID01)) have been suggested for compensating for the low uniformity of polycrystalline silicon pixels. Various other compensation units have also been suggested. However, circuits having the 2T-1C structure become complex due to the compensation device and it is difficult to design the circuit including the compensation device. In addition, the compensation device causes new problems.

Therefore, driving circuits for OLEDs having low leakage current, rapid response, and a simple structure are still desired and being researched.

### BRIEF SUMMARY OF THE INVENTION

The present invention provides an organic light emitting display having low power consumption and a long lifetime, and a method of fabricating the same.

According to an exemplary embodiment of the present invention, an organic light emitting display includes: a switching transistor which has a first silicon channel of low carrier mobility and a driving transistor which has a second silicon channel of relatively high carrier mobility.

According to another exemplary embodiment of the present invention, an organic light emitting display includes: a plurality of vertical scanning signal lines disposed parallel to each other and arranged on a substrate; a plurality of horizontal driving signal lines disposed parallel to each other and substantially perpendicular to the vertical scanning signal lines; a plurality of organic light emission diodes (OLEDs) defined by the vertical scanning signal lines and the horizontal driving signal lines, each OLED being disposed in each pixel of a plurality of pixels; a plurality of semiconductor circuit units connecting the vertical scanning signal lines and the horizontal driving signal lines, each semiconductor circuit unit driving a respective OLED; and a power supplying line supplying an OLED driving power to each semiconductor circuit unit, wherein each semiconductor circuit unit includes a switching transistor having a first channel of low carrier mobility and a driving transistor having a second channel of relatively higher carrier mobility.

The substrate may be formed of plastic.

The semiconductor circuit unit may include: an amorphous crystalline silicon switching transistor connected to the vertical scanning signal line and the horizontal driving signal line; a polycrystalline silicon driving transistor connected to the OLED; and one memory capacitor.

In an exemplary embodiment of the present invention, an insulating layer may be formed on the plastic substrate, and thus, a semiconductor circuit unit is formed on the insulating layer.

According to another exemplary embodiment of the present invention, a method of fabricating an organic light emitting display having a plurality of pixels arranged in a matrix on a substrate, each pixel having a switching transistor, a driving transistor, and an OLED is provided. The method includes: forming an amorphous crystalline silicon layer on the substrate; locally polycrystallizing the amorphous crystalline silicon layer to form an amorphous crystalline silicon region and a polycrystalline silicon region where a switching transistor and a driving transistor of each pixel are formed, respectively; forming a semiconductor circuit unit including the switching transistor and the driving transistor of each pixel using the amorphous crystalline silicon layer and the polycrystalline silicon region, respectively; and forming an OLED having an organic light emitting layer on the semiconductor circuit unit.

### BRIEF DESCRIPTION OF THE DRAWINGS

The above and other features and advantages of the present invention will become more apparent by describing in detail exemplary embodiments thereof with reference to the attached drawings in which:

FIG. 1 is an equivalent circuit schematic diagram of an exemplary embodiment of an organic light emitting display formed on a plastic substrate according to the present invention;

FIG. 2 illustrates an enlarged partial plan view of a layout of an exemplary embodiment of a pixel in the organic light emitting display of FIG. 1, according to the present invention;

FIG. 3 is a cross-sectional view of the organic light emitting display taken along line A-A″ of FIG. 2;

FIG. 4 is a cross-sectional view of the organic light emitting display taken along line B-B″ of FIG. 2; and

FIGS. 5A through 5P are plan views illustrating an exemplary embodiment of a process of fabricating a single crystalline silicon film according to the present invention.

### DETAILED DESCRIPTION OF THE INVENTION

Hereinafter, the present invention will be described more fully with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, lengths and sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

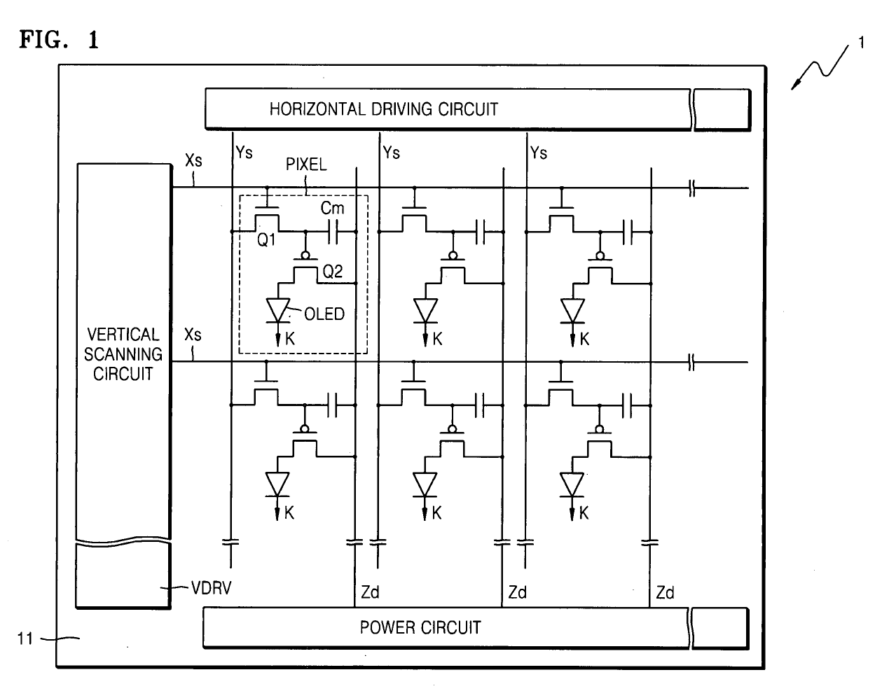

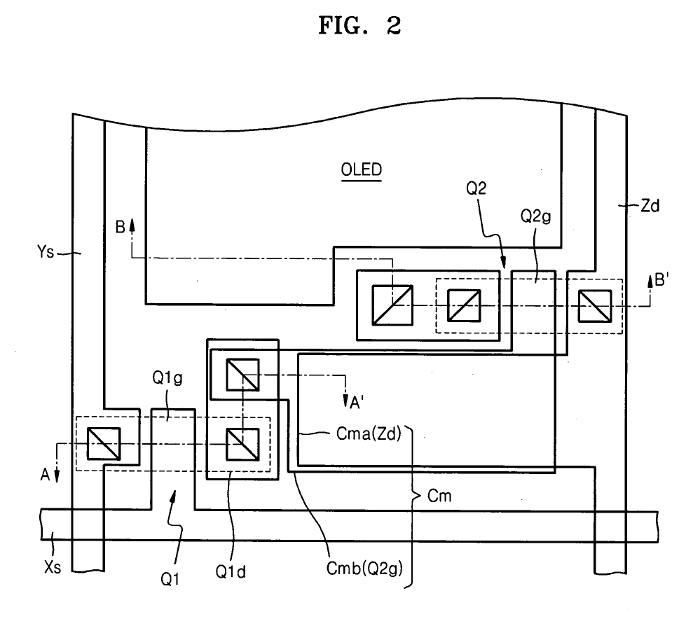

FIG. 1 is an equivalent circuit diagram illustrating a schematic structure of an exemplary embodiment of an organic light emitting display according to an exemplary embodiment of the present invention. FIG. 2 illustrates a partial enlarged plan view illustrating a layout of an exemplary embodiment of a pixel in the organic light emitting display of FIG. 1 according to the present invention.

Referring to FIG. 1, a display device 1 uses a plastic substrate 11 as a base panel. On the substrate 11, a plurality of parallel vertical scanning signal lines Xs (hereinafter “X lines”) and a plurality of parallel horizontal driving signal lines Ys (hereinafter “Y lines”) are disposed to cross each other and to form a matrix. In an exemplary embodiment, the horizontal driving signal lines Y lines Ys are disposed parallel to each other and substantially perpendicular to the vertical scanning signal lines X lines Xs. Z lines Zd are disposed parallel to the Y lines Ys with a predetermined distance between each of the Z lines Zd. Pixels (one shown with phantom lines) are defined on regions surrounded by the X lines Xs, the Y lines Ys and the Z lines Zd.

Vertical scanning signals are applied to the X lines Xs, and horizontal driving signals, that is, image signals, are applied to the Y lines Ys. The X lines Xs are connected to a vertical scanning circuit, and the Y lines Ys are connected to a horizontal driving circuit. The Z lines Zd are connected to a power circuit driving the organic light emitting diode (“OLED”).

Each of the pixels includes two transistors Q1 and Q2 and one capacitor (Cm). A source and a gate of a switching transistor Q1 in each pixel are connected to a respective X line Xs and Y line Ys, and a drain of the switching transistor Q1 is connected to a gate of a driving transistor Q2. A memory capacitor Cm accumulates electric charge applied by the operation of the switching transistor Q1 to store image information of the pixel, and is connected to a gate and a source of the driving transistor Q2 in parallel. An anode of the OLED is connected to a drain of the driving transistor Q2. A cathode K of the OLED acts as a common electrode shared by all of the pixels. Here, the switching transistor Q1 is an n-type TFT, and the driving transistor Q2 is a p-type TFT.

In the above described organic light emitting device, the switching transistor Q1 has a channel formed of silicon having low carrier mobility, for example, amorphous crystalline silicon, and the driving transistor Q2 has a channel formed of silicon having relatively higher carrier mobility, for example, polycrystalline silicon. The switching transistor Q1 having the low carrier mobility may have a channel formed of a mixture of amorphous crystalline silicon and partially polycrystalline silicon. The driving transistor Q2 may have a channel formed of pure polycrystalline silicon or a mixture of mostly polycrystalline silicon and partially amorphous crystalline silicon.

The channel in the switching transistor Q1 has low carrier mobility to satisfy a minimum response of switching pixels. Such a low carrier mobility can reduce off-current to decrease power loss caused by leakage current. A method of forming lightly doped drain (“LDD”) regions on both sides of a channel in a complementary metal-oxide-semiconductor (“CMOS”) to reduce off-current is well known, but this method requires an additional process for forming LDD masks and LDD regions. In addition, the LDD can be used in a semiconductor device having a substrate which can withstand heat such as a wafer, but cannot be used in a substrate which cannot withstand heat well, such as plastic, for example.

According to an exemplary embodiment of the present invention, glass or plastic, which cannot withstand heat well, is used as a substrate material. An amorphous crystalline silicon switching transistor and a polycrystalline silicon driving transistor are formed on the substrate without performing a process of forming LDD regions. In organic light emitting displays researched up to now, only one of amorphous crystalline silicon and polycrystalline silicon has been employed, but, in the present invention, both amorphous crystalline silicon, which has low carrier mobility to reduce off-current, and polycrystalline silicon, which has high carrier mobility to provide rapid response and long lifetime, are employed.

Referring to FIG. 2, the Y line Ys and the Z line Zd are disposed parallel to each other, and the X line Xs is disposed to cross the Y and Z lines Ys and Zd, respectively. The amorphous crystalline silicon switching transistor Q1 is located at a portion of each pixel where the X line Xs and the Y line Yd cross each other, and the polycrystalline silicon driving transistor Q2 is located around a portion of each pixel where the X line Xs and the Z line Zd cross each other. The memory capacitor Cm is disposed between the switching transistor Q1 and the driving transistor Q2. An upper electrode Cma of the memory capacitor Cm extends from the Z line Zd, and a lower electrode Cmb of the memory capacitor Cm is integrally formed with a drain Q1d of the switching transistor Q1 and a gate Q2g of the driving transistor Q2. A gate Q1g of the switching transistor Q1 is a portion extending from the X line Xs.

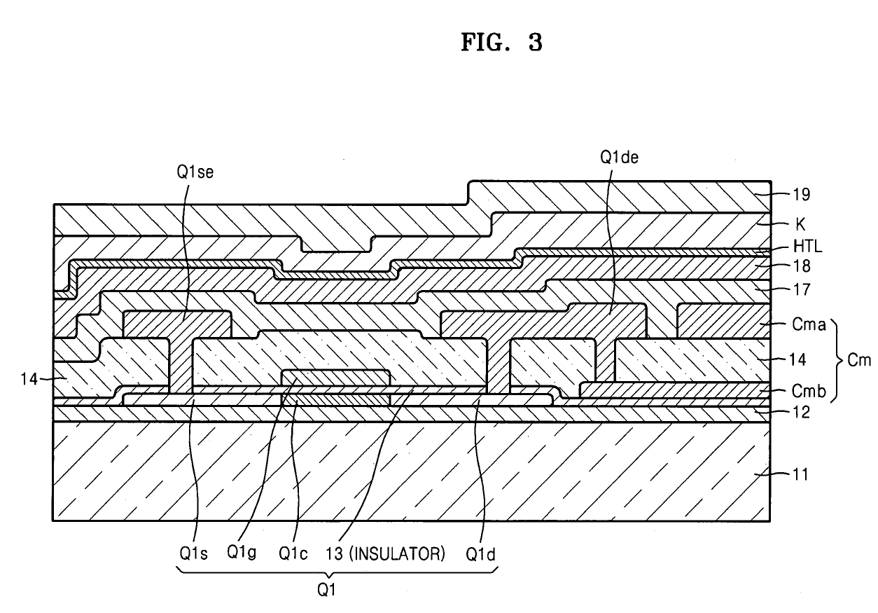

FIG. 3 is a cross-sectional view of the organic light emitting display of FIG. 1 taken along line A-A″ of FIG. 2. Referring to FIG. 3, a buffer layer 12 formed of an insulating material such as SiO₂ is formed on the plastic or glass substrate 11, and the switching transistor Q1 is formed on the buffer layer 12. The switching transistor Q1 includes an amorphous crystalline silicon layer having the source Q1s, a channel Q1c, and the drain Q1d formed on the buffer layer 12, a first insulating layer 13 formed of SiO₂, and the gate Q1g. An intermetal dielectric (“IMD”) 14 formed of SiO₂ is formed on the switching transistor Q1, and a source electrode Q1se and a drain electrode Q1de formed of metal are formed on the IMD 14. Lower portions of the source electrode Q1se and the drain electrode Q1de are electrically connected to the source Q1s and the drain Q1d through penetration holes formed in the IMD 14. The source electrode Q1se, the drain electrode Q1de, the upper electrode Cma of the memory capacitor Cm, and the Z line Zd can have Mo/Al/Mo or Ti/Al-Cu alloy/Ti structures. The gate Q1g of the switching transistor Q1 extending from the X line Xs is formed of tungsten.

A dielectric layer of the memory capacitor Cm is a part of the IMD 14, and the lower electrode Cmb is formed of tungsten and is integrally formed with the gate of the polycrystalline silicon driving transistor Q2 as described above.

A second insulating layer 17 and a third insulating layer 18 are sequentially formed on the upper electrode Cma integrally formed with the Z line Zd and on the source and drain electrodes Q1se and Q1de. In addition, a hole transport layer (“HTL”), a common electrode (“K”), that is, the cathode of the OLED, and a fourth insulating layer 19 are sequentially disposed on the second and third insulating layers 17 and 18. The fourth insulating layer 19 is a passivation layer for protecting the OLED.

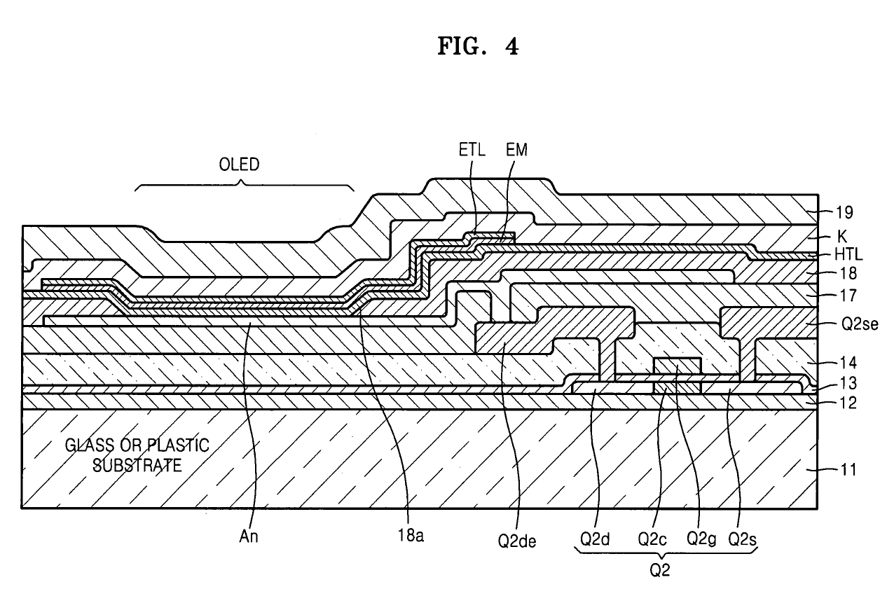

FIG. 4 is a cross-sectional view of the OLED taken along line B-B″ of FIG. 2, and illustrates the entire stacked structure of the driving transistor Q2 and the OLED.

The buffer layer 12 is formed on the plastic or glass substrate 11, and the driving transistor Q2 that is formed simultaneously with the switching transistor Q1 is formed on the buffer layer 12. A silicon layer of the driving transistor Q2 is simultaneously formed with the silicon layer used to fabricate the switching transistor Qs, and is then polycrystallized in an additional annealing operation. The polycrystalline silicon layer includes a source Q2s, a channel Q2c, and a drain Q2d, and the first insulating layer 13 formed of SiO₂ and the gate Q2g are sequentially formed. The gate Q2g is integrally formed with the upper electrode Cma of the memory capacitor Cm (see FIG. 3) using tungsten, as described above.

The IMD 14 formed of SiO₂ covering the switching transistor Q1 is formed on the polycrystalline driving transistor Q2, and the source electrode Q2se and the drain electrode Q2de formed of metal are formed on the IMD 14. The lower portions of the source and drain electrodes Q2se and Q2de are electrically connected to the source Q2s and the drain Q2d, respectively, through respective penetration holes formed in the IMD 14, and the second and third insulating layers 17 and 18 are sequentially formed on the source and drain electrodes Q2se and Q2de.

The HTL is disposed on the third insulating layer 18, and a light emitting layer (“EM”) and an electron transport layer (“ETL”) are sequentially formed on a predetermined region of the HTL. Then, the common electrode K, that is, the cathode, is formed on the stacked structure of the HTL, EM, and ETL. The fourth insulating layer 19 is formed on the common electrode K. An anode (“An”) that is connected to the drain electrode Q2de and located under the OLED is disposed between the second and third insulating layers 17 and 18. The anode An physically contacts the HTL through a window 18a formed on the third insulating layer 18 allowing electrical connection between the anode An and the HTL.

The above described layout of the organic light emitting display is an exemplary embodiment of the present invention, and the above layout and modifications thereof do not limit the scope of the present invention.

In the organic light emitting display according to the current exemplary embodiment of the present invention, a semiconductor circuit unit having low leakage current and long lifetime for driving the OLED is formed on a substrate that does not withstand heat well, such as a plastic substrate.

An exemplary embodiment of a method of fabricating the organic light emitting display according to the present invention will be described as follows.

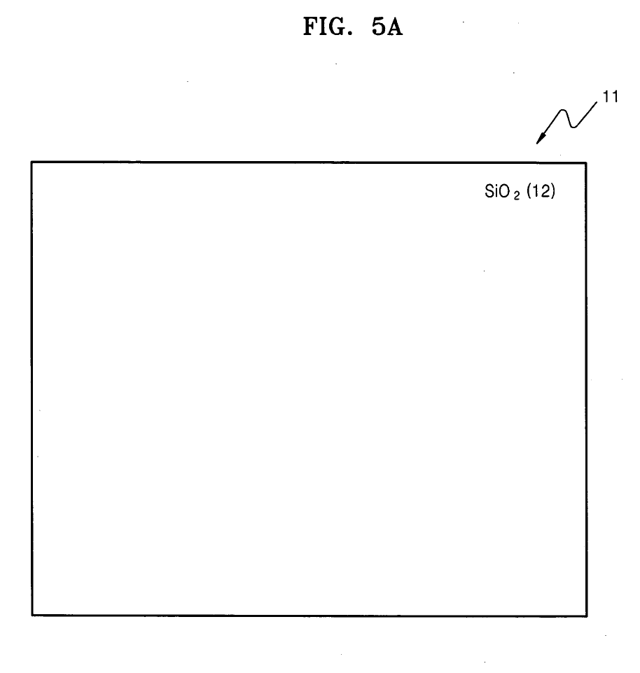

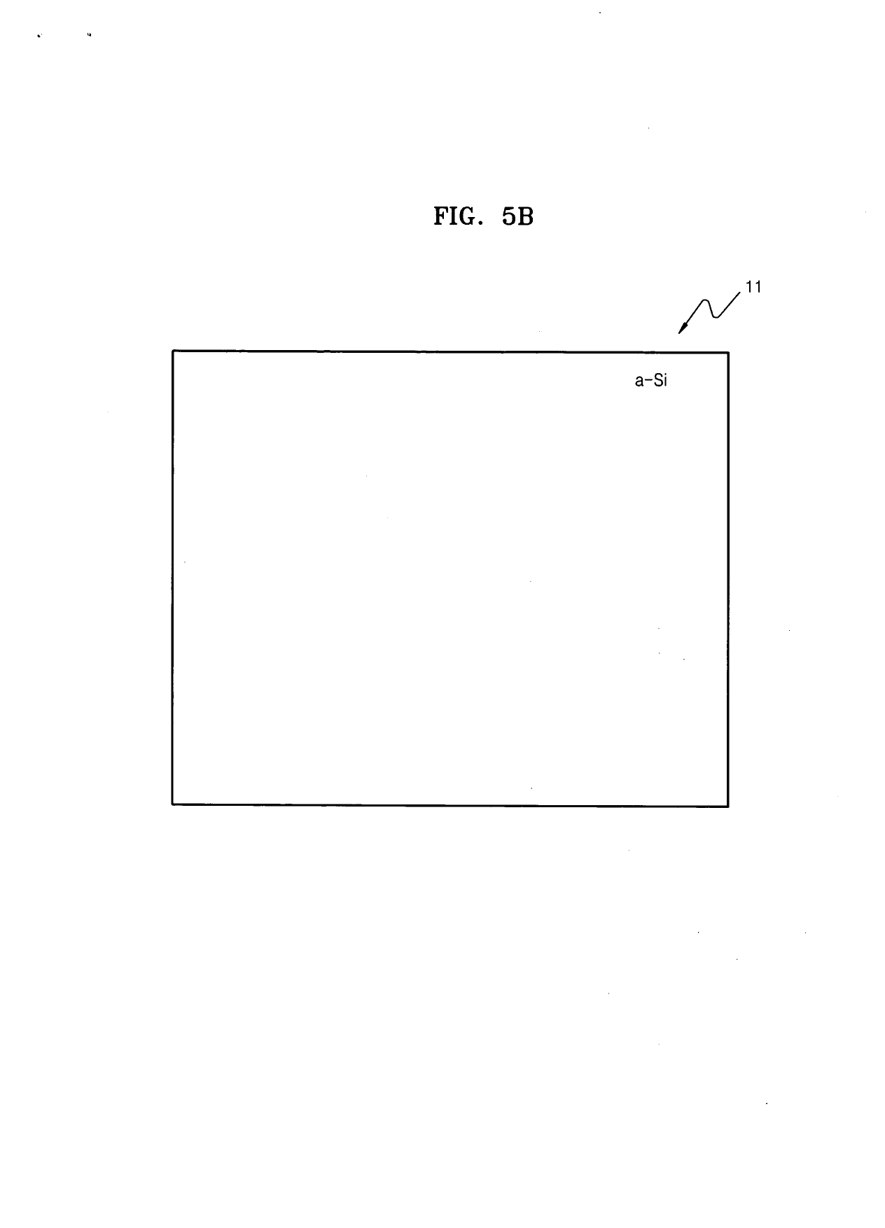

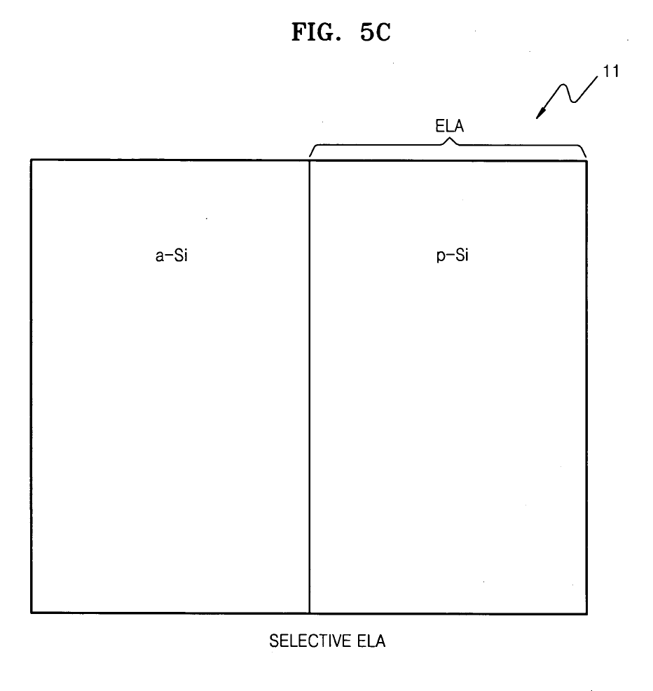

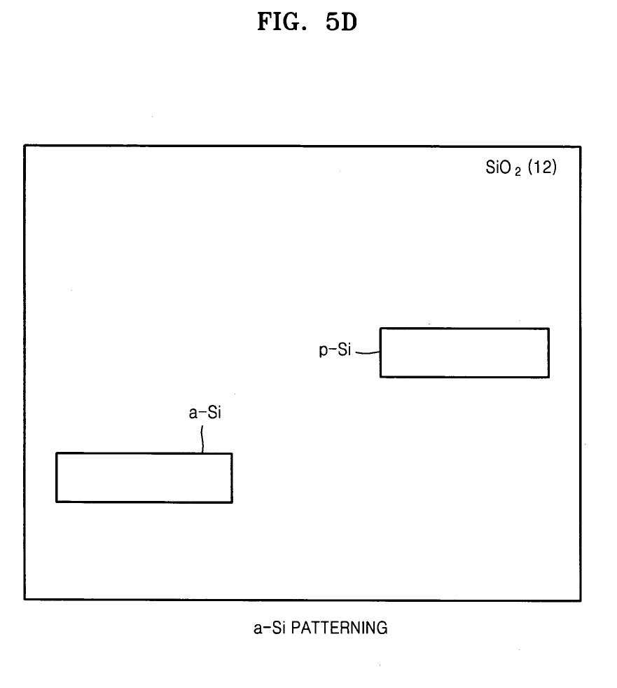

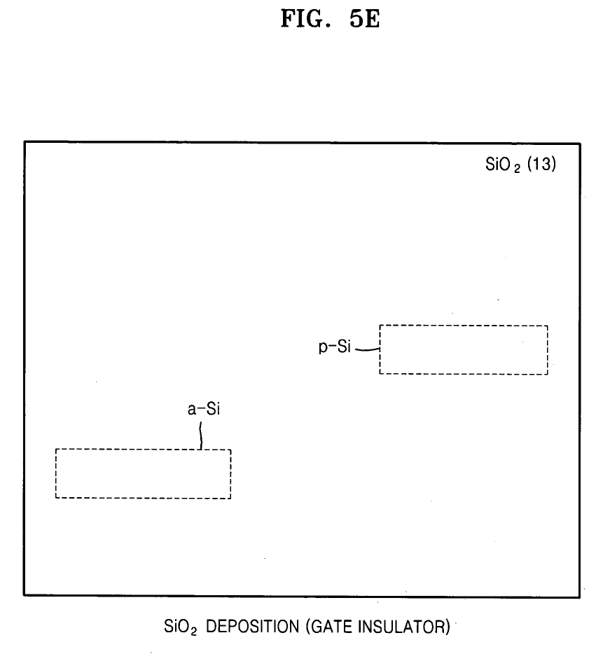

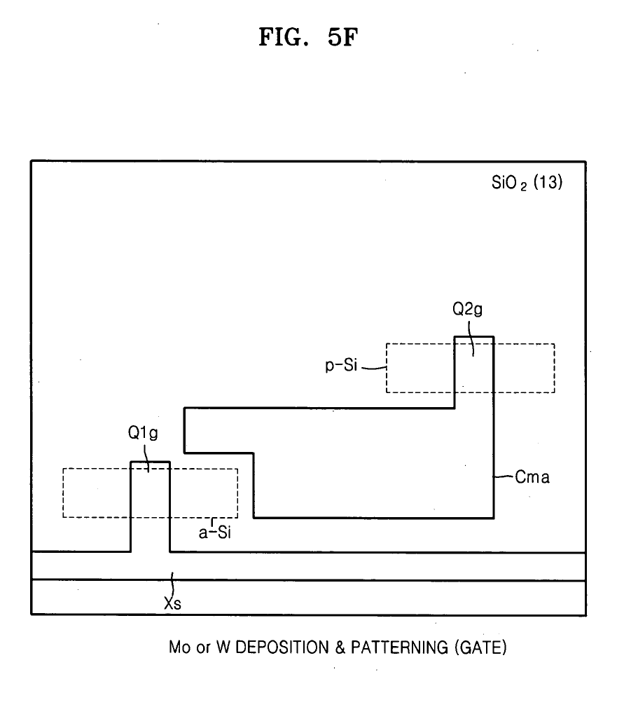

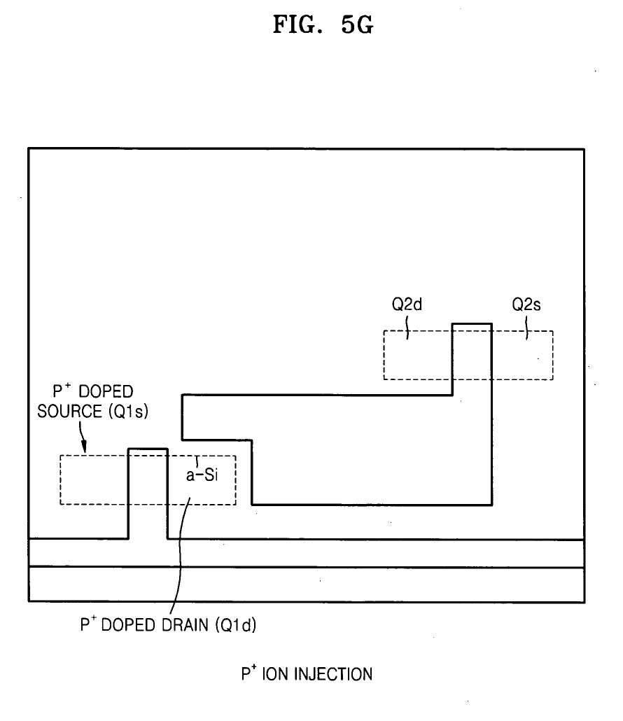

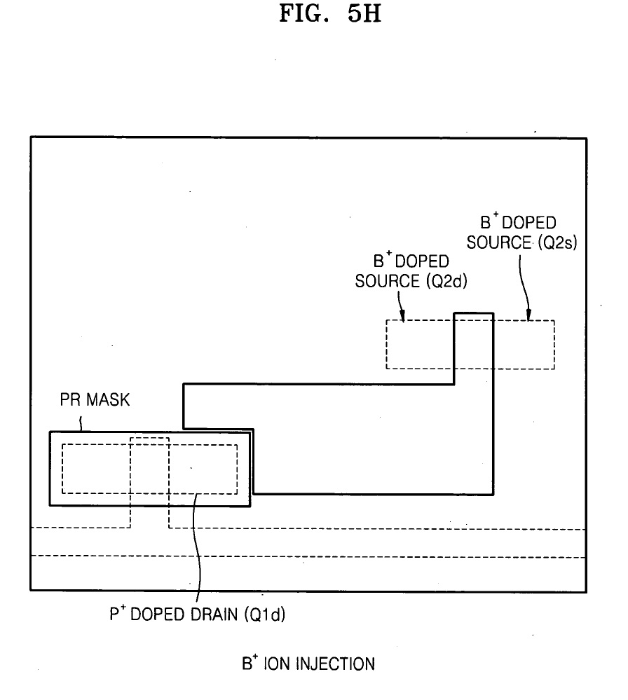

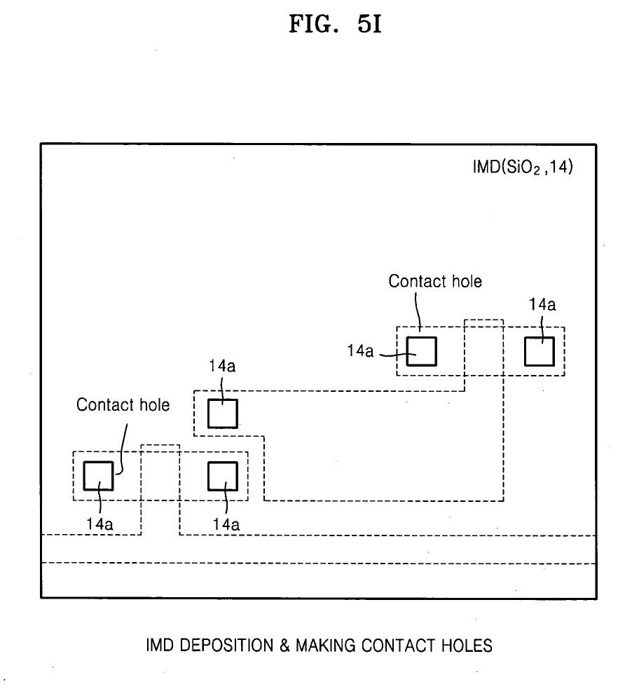

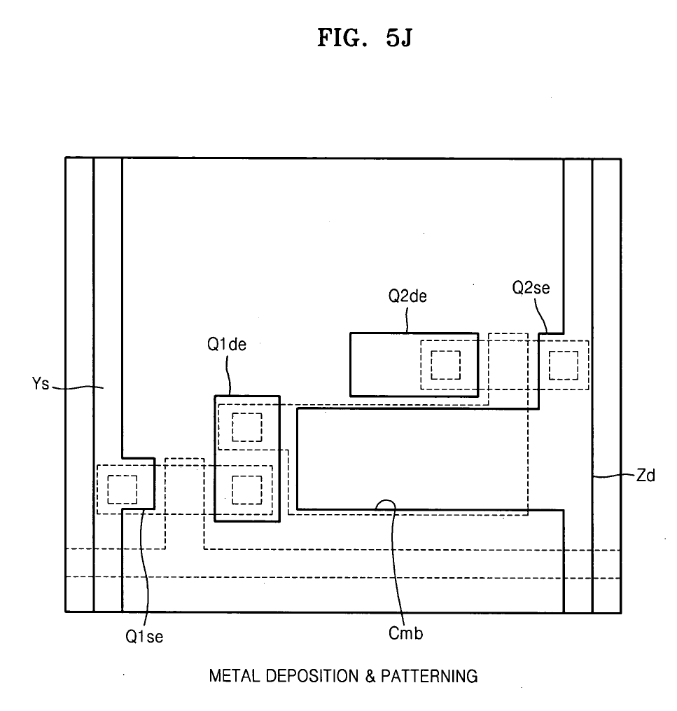

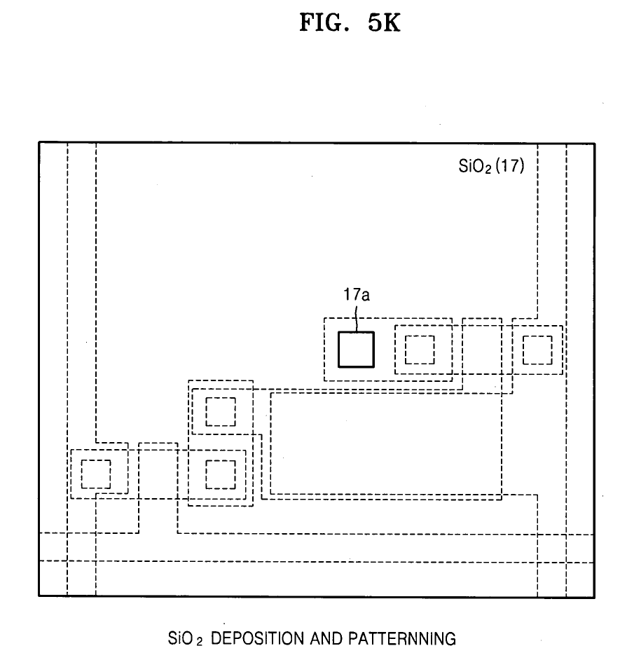

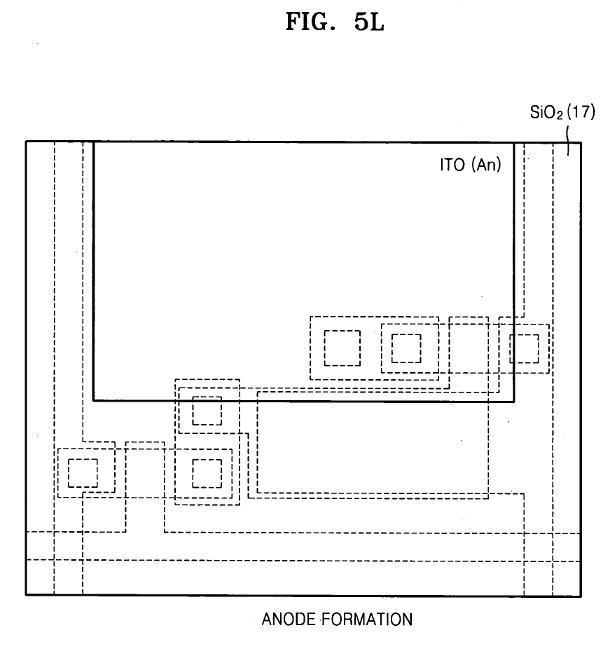

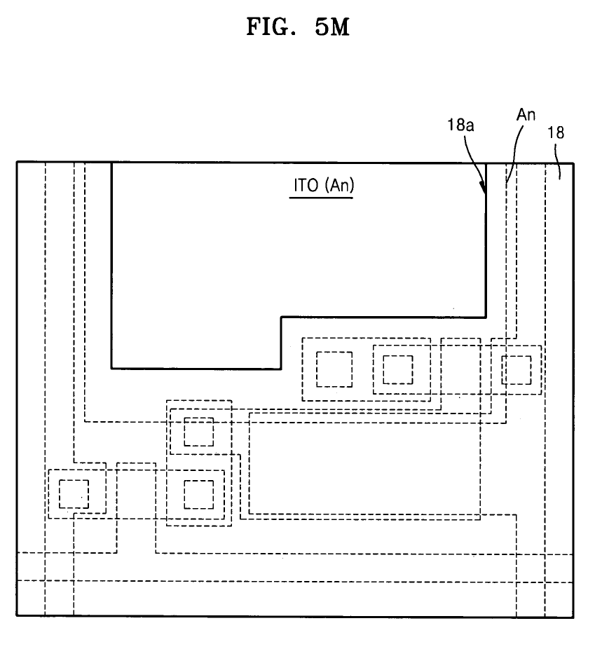

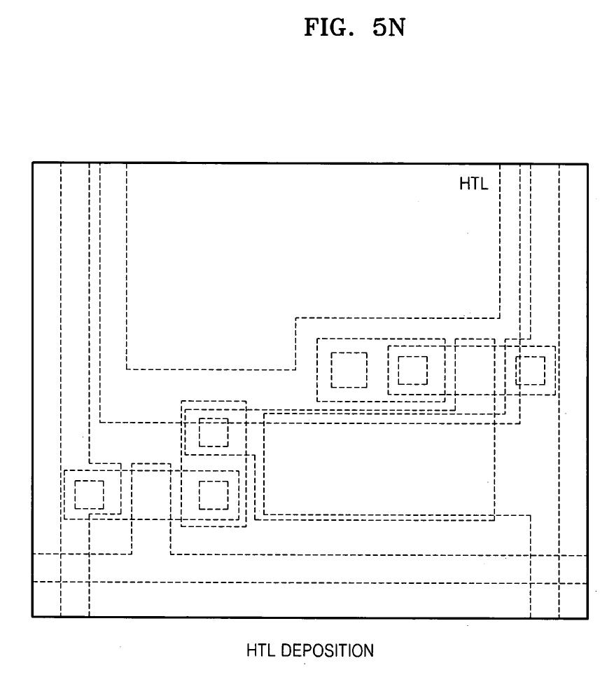

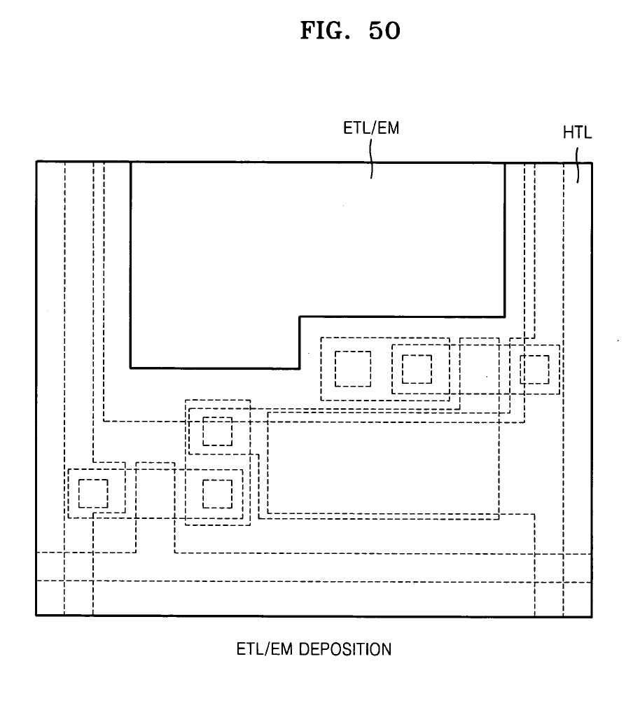

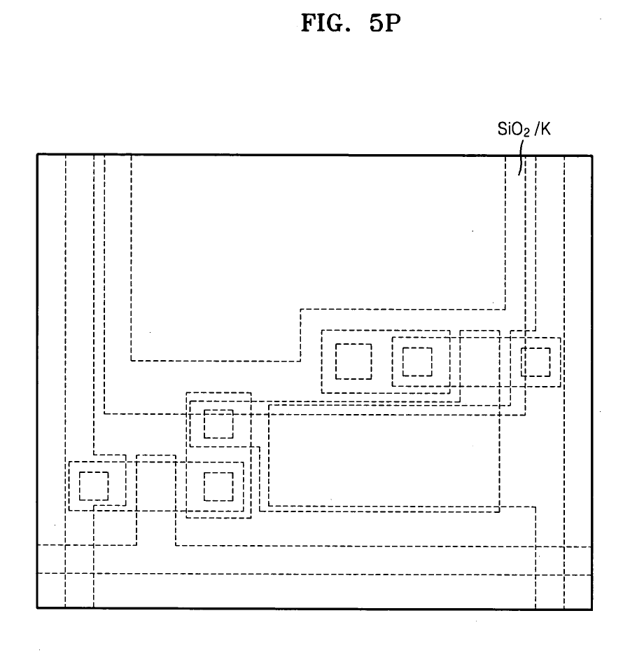

FIGS. 5A through 5P are views illustrating an exemplary embodiment of a process of fabricating a semiconductor circuit unit, according to the present invention. Referring to FIG. 5A, a SiO₂ buffer layer 12[Note: reference character “(12)” should be replaced with an underlined “12” in FIG. 5A to avoid objection by the Examiner] is formed on a glass or plastic substrate 11 using, for example, a chemical vapor deposition (“CVD”) method. FIGS. 5A through 5P illustrate a portion corresponding to a unit pixel of the organic light emitting display.

Referring to FIG. 5B, amorphous crystalline silicon a-Si is formed on the buffer layer 12.

Referring to FIG. 5C, the amorphous crystalline silicon a-Si is selectively annealed using a mask (not illustrated) by excimer laser annealing (“ELA”), and thus the amorphous crystalline silicon a-Si where the driving transistor Q2 is formed is changed to polycrystalline silicon p-Si.

Referring to FIG. 5D, the amorphous crystalline silicon a-Si and the polycrystalline silicon p-Si are patterned to form silicon islands that will be used to form the switching transistor Q1 and the driving transistor Q2, respectively. The amorphous crystalline silicon a-Si and the polycrystalline silicon p-Si are simultaneously patterned using a well-known conventional patterning method, for example, a photolithographic method, but is not limited thereto.

Referring to FIG. 5E, a gate insulating layer 13 formed of, for example, SiO₂, is deposited using a CVD method.

Referring to FIG. 5F, a Mo metal layer or W metal layer is formed on the gate insulating layer 13 using a vapor deposition method or a sputtering method, and is patterned in a wet-etching method using a photoresist to form the X line Xs, the gates Q1g and Q2g, and the lower electrode Cmb of the memory capacitor Cm.

Referring to FIG. 5G, phosphorus (P+) ions are injected into the amorphous crystalline silicon a-Si that is not covered by the gates Q1g and Q2g (see FIG. 5F) using an ion injection process to obtain the source Q1s and the drain Q1d of the switching transistor Q1. If a mask protecting the polycrystalline silicon of the driving transistor Q2 is additionally deposited on the gate insulating layer 13, the polycrystalline silicon of the driving transistor Q2 is not doped.

Referring to FIG. 5H, after forming a photoresist mask (“PR MASK”) protecting the switching transistor Q1, boron (B+) ions are injected into the silicon to obtain a p-type source Q2s and drain Q2d of the driving transistor Q2. If the driving transistor Q1 is N-doped previously, it is converted into a p-type transistor through the sufficient doping of B+ ions. After doping P+ ions and B+ ions, single crystalline silicon of the switching transistor Q1 and single crystalline silicon of the driving transistor Q2 are activated through an annealing process. The process in FIG. 5H is optional and may be omitted. If omitted, the amorphous crystalline silicon a-Si and the polycrystalline silicon p-Si should be doped in the process described with respect to FIG. 5G, and thus two transistors obtained from the above process are NPN type transistors.

Referring to FIG. 51, SiO₂ is deposited on the uppermost stacked layer of the substrate 11 using a CVD process to form the IMD 14, and contact holes 14a are formed in the IMD 14 for contacting the switching transistor Q1 and the driving transistor Q2.

Referring to FIG. 5J, a metal layer is deposited on the IMD 14 and patterned to form the Y line Ys, the Z line Zd, the source and drain electrodes Q1se and Q1de of the switching transistor Q1, the source and drain electrodes Q2se and Q2de of the driving transistor Q2, and the upper electrode Cma of the memory capacitor Cm.

Referring to FIG. 5K, the second insulating layer 17 formed of SiO₂ is deposited on the above stacked layers, and a contact hole 17a exposing the drain electrode Q2de of the driving transistor Q2 (see FIG. 5J) is formed in the second insulating layer 17.

Referring to FIG. 5L, a conductive material such as indium tin oxide (ITO) is formed on the second insulating layer 17, and is patterned to form the anode An of the OLED.

Referring to FIG. 5M, the third insulating layer 18 is formed on the above stacked layers, and the window 18a exposing the ITO anode An is formed on the OLED region.

Referring to FIG. 5N, the HTL is deposited on the entire upper surfaces of the third insulating layer 18 and the ITO anode An.

Referring to FIG. 50, the EM and the ETL are sequentially deposited on the HTL.

Referring to FIG. 5P, the common electrode K, that is, the cathode of the OLED and the fourth insulating layer 19 (See FIG. 4) formed of SiO₂ are sequentially deposited on the uppermost stacked layer including the ETL to obtain the organic light emitting display.

Processes of fabricating the transistor and capacitor driving the pixel are described above. According to the current exemplary embodiments of the present invention, an amorphous crystalline silicon switching transistor and a polycrystalline silicon driving transistor are formed on the plastic substrate.

In the present invention, the switching transistor, where low leakage current is desired, is formed of amorphous crystalline silicon having low carrier mobility, and the driving transistor, where good durability and rapid response are desired, is formed of polycrystalline silicon having high carrier mobility.

According to the organic light emitting display of the present invention, the organic light emitting display has low current leakage, good durability and rapid response, resulting in high resolution, low power consumption and long lifetime.

Since the LDD structure for reducing off-current is not employed in the present invention, plastic or glass which cannot withstand heat well, can be used for a substrate. According to the present invention, an organic light emitting display having high performance thus can be fabricated.

While the present invention has been particularly shown and described with reference to exemplary embodiments thereof, the present invention should not be construed as being limited to the exemplary embodiments set forth herein; rather, these embodiments are provided so that this disclosure will be thorough and complete, and will fully convey the concept of the present invention to those skilled in the art. It will be understood by those of ordinary skill in the art that various changes in structure and arrangement may be made therein without departing from the spirit and scope of the present invention as defined by the following claims.

What is claimed is:

1. An organic light emitting display comprising:
a substrate;
a plurality of pixels arranged in a matrix on the substrate, each of the plurality of pixels having a switching transistor, a driving transistor and an organic light emitting diode (OLED),
wherein the switching transistor comprises a channel having low carrier mobility and the driving transistor comprises a channel having relatively higher carrier mobility.

2. The organic light emitting display of claim 1, wherein the channel in the switching transistor is formed of amorphous crystalline silicon and the channel in the driving transistor is formed of polycrystalline silicon.

3. The organic light emitting display of claim 1, wherein the substrate is formed of one of glass and plastic.

4. An organic light emitting display comprising:
a plurality of vertical scanning signal lines disposed parallel to each other and arranged on a substrate;
a plurality of horizontal driving signal lines disposed parallel to each other and substantially perpendicular to the vertical scanning signal lines;
a plurality of organic light emitting diodes (OLEDs) defined by the vertical scanning signal lines and the horizontal driving signal lines, each OLED of the plurality of OLEDs being disposed in each pixel of a plurality of pixels;
a plurality of semiconductor circuit units connecting the vertical scanning signal lines and the horizontal driving signal lines, each semiconductor circuit unit driving a respective OLED; and
a power supplying line supplying an OLED driving power to each semiconductor circuit unit of the plurality of semiconductor circuit units,
wherein each semiconductor circuit unit of the plurality of semiconductor circuit units comprises a switching transistor having a first channel of low carrier mobility and a driving transistor having a second channel of relatively higher carrier mobility.

5. The organic light emitting display of claim 4, wherein the first channel in the switching transistor is formed of amorphous crystalline silicon and the second channel in the driving transistor is formed of polycrystalline silicon.

6. The organic light emitting display of claim 4, wherein the substrate is formed of one of glass and plastic.

7. The organic light emitting display of claim 5, wherein the substrate is formed of one of glass and plastic.

8. A method of fabricating an organic light emitting display having a plurality of pixels arranged in a matrix on a substrate, each pixel having a switching transistor, a driving transistor and an organic light emitting diode (OLED), the method comprising:
forming an amorphous crystalline silicon layer on the substrate;
locally polycrystallizing the amorphous crystalline silicon layer forming an amorphous crystalline silicon region and a polycrystalline silicon region where a switching transistor and a driving transistor of each pixel are formed, respectively;
forming a semiconductor circuit unit comprising the switching transistor and the driving transistor of each pixel using the amorphous crystalline silicon layer and the polycrystalline silicon region, respectively; and
forming an OLED having an organic light emitting layer on the semiconductor circuit unit.

9. The method of claim 8, wherein the substrate is formed of one of glass and plastic.

10. The method of claim 8, wherein the local polycrystallization of the amorphous crystalline silicon layer is performed using an excimer laser annealing (ELA) process.

11. The method of claim 9, wherein the local polycrystallization of the amorphous crystalline silicon layer is performed using an ELA process.
